(19) United States
(12) Patent Application Publication
(10) Pub. No.: US 2011/0100456 A1
(43) Pub. Date: May 5, 2011

(54) Solar Heating Apparatus

(76) Inventor: Jack O'Neal Walden, Tucson, AZ (US)

(21) Appl. No.: 12/608,355

(22) Filed: Oct. 29, 2009

(51) Int. Cl. H01L 31/00

(52) U.S. Cl. 136/259

(57) ABSTRACT

This invention solves the problem of the high cost of man-made energy. Page 1 of 9. FIG. 1, Oven, depicts how the highly collimated Sun-light is captured, compounded and distributed to the end destination for beneficial use. It should be noted that the Sun's light-rays can be compounded many times for a more powerful ray of highly collimated light/heat energy to be distributed for beneficial use. It should also be noted that there are many variations in the proper placing of the various components using both conical and parabolic reflectors and lenses.

### BACKGROUND OF THE INVENTION

1. Field of Invention

The present invention relates generally to Sunlight-energy distribution systems and more particularly to a solar-energy system(s) for reducing energy consumption and improving consumption efficiency.

2. Description of the Prior Art

Recently the cost of energy has increased sharply. Although recent increases are due in large part to artificial factors such as the maintenance of oil prices by large cartels, the increases also reflect the growing scarcity of energy producing fuels. In order to lessen the immediate impact of such scarcities as well as to postpone the inevitable day when these fuels are exhausted, it is in the public interest that everyone should conserve energy. Of course, the previous increases in the cost of energy coupled with the inevitable larger future increases make conservation even more individually attractive.

Unfortunately, many energy consuming devices and their loads were designed during the time when energy was cheap and conservation seemed relatively unimportant. In so far as the cost is based upon the total amount of energy used, a reduction in usage will reduce the costs accordingly.

No prior art was found related to this method of gathering of the Sun's rays for beneficial use.

It is therefore an object of the present invention to provide for the Beneficial Use of “solar-light energy” for reducing the amount of man-made energy consumed.

The solar-collector would typically be located on rooftops for the gathering of the Sun's rays. The collection units would have to be manufactured. While some could be sized to cover general and similar loads others would, no doubt, have to be individually sized to the specified requirements of the individual application. Some filtering of the light-rays may be necessary, which can be easily accomplished with various existing filters and prisms which are readily available in the market place. The solar-collector would be typically manufactured with the altazimuth telescope-type mount, also known as an alt-azimuth mount, similar to the celestial telescopes used for stargazing, and which can be easily and reasonably inexpensive to build. The solar-collector will gather the sunlight and compound it into a smaller beam, and direct the said smaller beam downward in an exact, or nearly exact, perpendicular direction, or the vertical from a given point.

Some research and development will be required to perfect the various applications. This and other objects and advantages of the present invention will no doubt become apparent to those skilled in the arts after having read the following detailed description of the preferred embodiment which is illustrated in the below drawings.

The Sun's energy—Solar light—is used in these original ideas and should be so considered. The present invention, in its entirety, should be considered in the true spirit in which it is presented.

Please see page 5 of 9, FIG. 6;

The Sun 20 emits solar rays 22 and they are reflected (first reflected rays) 44 from the solar collector (Exterior mirror coated corneal reflector) 40 to the Interior mirror coated conical reflector 42 where the sun rays are again reflected (second reflected rays) 46 and down to the hinged minor (third reflected rays), and on down to the precision-ground lens 50 (third reflected rays fine tuned by redirecting of the light rays).

It should be pointed out that by increasing the diameter of the Exterior mirror coated conical reflector 40, of the solar collector, will transmit a more intense amount of light to the Interior mirror coated conical reflector 42. The precision-ground lens 50 converts the somewhat random solar rays into a more coherent beam of light designated Precision focused rays 52, much like a laser beam. The secondary auxiliary heater is energized to augment, especially when solar rays are not available for constructive use.

No prior art was found related to this method of the gathering of Sunlight and using the Light-energy Beam for Beneficial Use. It will no doubt become apparent to those stilled in the arts that the present invention is new and unique.

### SPECIFICATIONS

An Alternative Energy solar-light energy collection and distribution system and incorporating an electrical, natural gas, or any other man-made backup system for when solar rays are unavailable. for reducing the power consumption of a plurality of loads comprising:

means for tracking the Sun when it is visible;

means for tracking the Sun when it is not visible;

means for collecting the light-rays of the sun;

means for compounding the light-rays of the sun;

means for redirecting and focusing the light-rays into a coherent beam of light;

means for distributing the light rays to an end destination for beneficial use;

Turning now to page 1 of 9, FIG. 1, a rudimentary drawing illustrating a preferred embodiment of an alterative energy solar-light collection and distribution system in accordance with the present invention is shown. The Sun, being 93 million miles away, is about the very best or is the best “Point Source” of light energy known to man. Any point, no matter how small, has breadth; the 93 million miles to the Sum nearly nulls out that reality.

The basic system, page 5 of 9, which is generally designated by FIG. 6, is typically located on a rooftop for the collection of the Sun's rays.

The Sun, a giant laser, being 93 million miles from Earth, is the greatest point-source light in existence. The light-rays emanating from the Sun are photons, traveling 93 million miles in distance is a nearly-perfectly collimated form. The intent of this invention is to capture those highly collimated light-ray photons and gently redirect them in several directions, while greatly compounding them and keeping them in a highly parallel form to be delivered to the final destination.

### Sun Tracker Control Relay Units

The schematic illustration, FIG. 7, on page 6 of 9 represents two (2) Light-Dark-Sensor-Circuit-Relays (LDR's) used to control the Solar Tracking Motor Mechanisms to maintain proper orientation with the Sun. The LDR's are available from the Renewable Energy Shop Company, which is located in the United Kingdom. (The electronic circuitry is currently located on perforated boards, complete with external connection points for photocell, voltage and relay output for motor control, and contain anti-chatter relay circuitry as well as a light sensitivity adjustment.)

The “fuzzy” round “O”, located in the center of page 6 of 9, FIG. 7, between the two relay schematics, in close proximity to the two LDR's {A Light Dependent Resistor (aka LDR, photoconductor, or photocell) is a device which has a resistance which varies according to the amount of light falling on its surface.} is actually a representation of a Sunspot, projected from sunrays that are traveling through a relatively small-bore tube onto a flat surface, or plane, in close proximity to the two LDR's. The small-bore tube is aimed at the Sun, and which can be of any desired length or bore for any varied sensitivity. The sunray-transmission tube, guiding the parallel-rays exiting from the tube to the Sunspot, is properly and safely aimed without directly gazing at the Sun.

The close proximity of the LDR's sensitivity can be further enhanced by incorporating a flexible razor-thin surgical blade, such as the new surgical razor-blade as recited in U.S. Pat. No. 5,628,759 which is extended out in a slanted manner into the light beam and redirecting light to the photocell.

The envisioned Solar-tracking mounting is of the altazimuth telescope-type mount, also known as an alt-azimuth mount, that allows up and down piveting (changes in altitude, or elevation, from 0° to 90°) together with horizontal rotation (changes in azimuth by ±180°). This and other objects and advantages of the present invention will no doubt become apparent to those skilled in the arts of celestial star gazing of the simplicity of construction and operation, after having read the following detailed description of the preferred embodiment which is illustrated in the below drawing(s).

To track an object across the sky with such an arrangement demands that the Solar Collector Unit move simultaneously around two axes—a complication that, in the past, led to an overwhelming preference for equatorial mountings. However, computer control has made alt-azimuthal operation so much easier, that alt-azimuth mountings, which are simple to construct, have been adopted almost universally for large modern units. The vertical axis is a fork that holds the two ends of the horizontal axis, and the horizontal base can be spun around a vertical axis at its center. Because there are no difficult angles to sustain, it takes a less massive, less expensive mount to support a given size unit.

Alt-azimuth coordinate system, or horizon coordinate system, is an astronomical coordinate system in which the position of a body on the celestial sphere is described relative to an observer's celestial horizon and zenith. The coordinates of a body in this system are its altitude and azimuth. Altitude is measured from the celestial horizon along the vertical circle through the body and the zenith of the observer. Azimuth is measured along the celestial horizon from the observer's south point (the point on the horizon directly south of him) to the point where the body's vertical circle intersects the horizon. Because the earth rotates on its axis, the altitude and azimuth of a celestial body are constantly changing.

The object of the present control system is to keep the reflected beam of sunlight in an absolutely perpendicular orientation—no matter the time of day or the angle of the Sun—in relation to the Solar Collector. One of the LDR's will control the motor to position the altitude, while the other LDR will control the motor to position the azimuth of the Solar Collector Unit. Additional LDR units can be incorporated—if need be—for further fine tuning of the directed light-beam. Further—although not anticipated at this time—as mentioned above, a computer can be incorporated to fine-tune the tracking of the until to an even greater degree of tracking. Because of the control by the LDR's, which are constantly monitoring the location and shape of the sun-spot, the altitude and azimuth of the celestial body is constantly negating the effect of the rotating of the earth on its axis. A simple timing motor(s) can position the unit in the absence of direct sun-light.

It should be pointed out that there are many variations of design, and layouts and arrangements as illustrated in the below-mentioned drawings. For example, the Solar Collector can be comprised of either Conical or Parabolic Reflectors and can be with or without lenses and, all major components are interchangeable. If a lens is used, it can be located in any position that is desired to compliment that particular arrangement. The Sun-ray Compounding Units can be located as desired also, and as many compounding units as desired can be utilized. It should be understood that there are no limits, except practically, that limits the amount of compounding of the Sun's rays? Those skilled in the arts can readily see that the various arrangements of the solar collectors can also be used to bake bread, generate hot water, and even steam and more, in conjunction with a heat-transfer devise. Whenever “heat” is needed and, for any purpose, this system can arise to the occasion and supply low-cost solar heat for the consumer.

The various concepts of compounding of the Solar-rays are used in this original idea and should be so considered. The present invention, in its entirety, should be considered in the true spirit in which it is presented.

### SUMMARY Of THE PRESENT INVENTION

It is therefore an object of the present invention to provide a new laser-like-beam of natural Sun-energy, for energy distribution systems, for reducing the amount of energy in which is consumed by a plurality of heating loads.

The present invention would/could possibly be manufactured by an existing manufacturer, or small private manufacturing facilities could be started up for that purpose. There would be a ready market for many different sizes of units.

The inside conical reflector of the compounding lens assembly may be connected to the outer conical lens reflector for precision control of the Sun's rays.

The “Concentrator”, with Sun-tracking mechanism is typically located on a rooftop for the tracking of the Sun, and for the collection of the Sun's rays.

It should be pointed out that there are many variations of design, and layouts and arrangements of the various components. For example, the Compounding Collector can be comprised of either Conical or Parabolic Reflectors and can be with or without lenses, If a lens is used, it can be located in any position that is desired to compliment that particular arrangement. The Light-ray Compounding Units can be located as desired also, and as many compounding units as desired can be utilized. It should be further understood that there are as many variations of design, and layouts and arrangements as illustrated in the below-mentioned drawings. There are no limits, except practicality, on the number of different sizes being made available. It should he further understood that there are no limits, except practically, that limits the amount of compounding of the Sun's light rays? They—the Sun's light rays—are used in this original idea and should be so considered. The present invention, in its entirety, should be considered in the true spirit in which it is presented.

### BRIEF DESCRIPTION OF THE DRAWINGS

FIG. 1, illustrates how an oven might be heated and shows how the heat of the Sun-light is captured, compounded and distributed to the end point for beneficial use. Please note the additional lens assembly for fine tuning the light beam.

FIG. 2, illustrates how a steam boiler might be heated, as in FIG. 1 above.

FIG. 3, illustrates how the conical reflectors can be replaced by the parabolic reflectors and further compounding of the Sun's rays by the secondary conical reflectors.

FIG. 3, also is a drawing illustrating the Sun as the point-light source with two (2) parabolic reflectors generating the primary gathering of the Sun's rays and two (2) conical reflectors, and indicates that there are unlimited variations of compounding the object of the present control system is to keep the reflected beam of sunlight in an absolutely perpendicular orientation—no matter the time of day or the angle of the Sun—in relation to the Solar Collector. Please note also that the drawing illustrates that the reflectors can be liquid cooled.

FIG. 4, illustrates how a furnace could be heated by the above depicted system. A damper could shut off the heat when the temperature is on control or when not needed. This concept should work nicely for an insert for an existing fireplace; also for a new stand-alone unit.

FIG. 5, illustrates how a boiler could be heated by the above depicted system. The spiral coil can be aluminum finned or the coil can be replaced by the conventional water tubes.

FIG. 6, illustrates the basic system that applies to all of the above depicted systems. A method to prevent overheating can be applied to all of the aforementioned systems and, all of the aforementioned systems can have auxiliary backup heating.

FIG. 7, is a schematic diagram of the Light-Dark Relay schematics as supplied by Renewable Energy Shop Company which is located in the United Kingdom and illustrates the control system designed to maintain the altitude and azimuth of the roof top mounted solar collector.

FIG. 8, illustrates the single lens assembly of the compounding conical reflectors. Please note the indentation for centering the interior reflector.

FIG. 9, illustrates the double lens assembly of the compounding conical reflectors. Please note, also, the indentation for centering the interior reflectors.

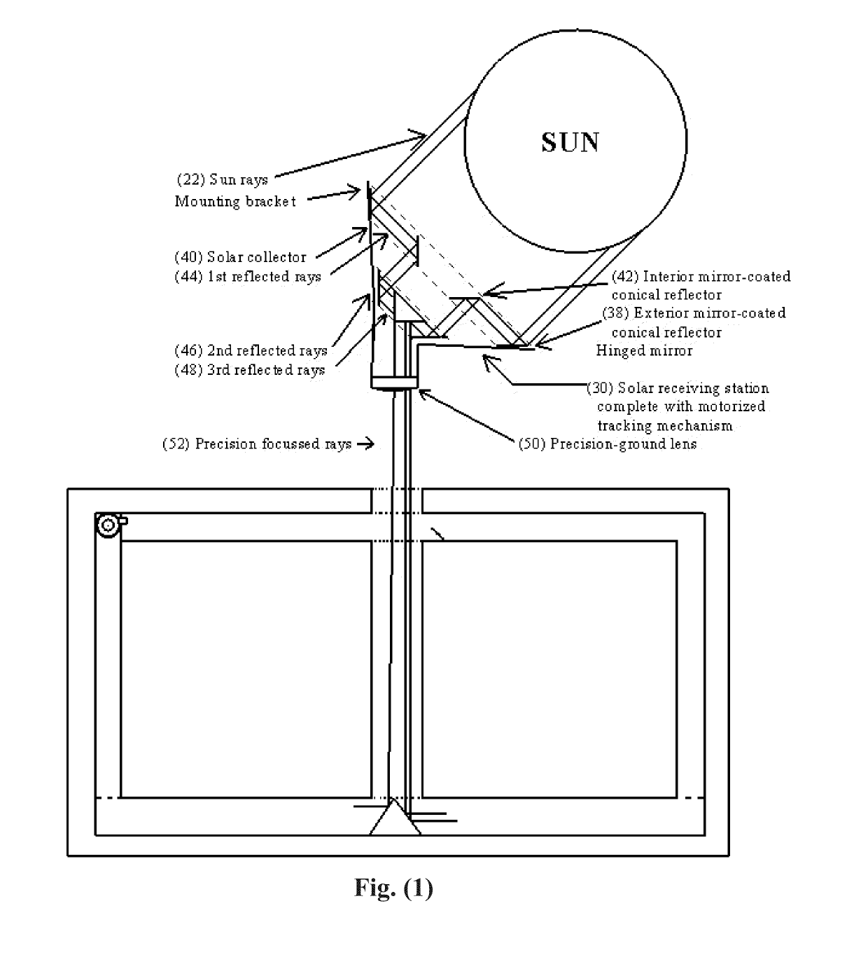

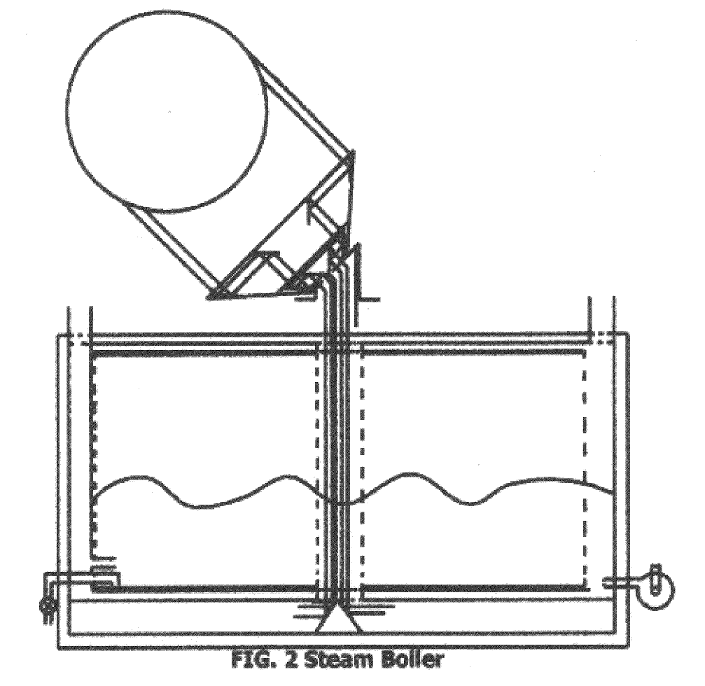

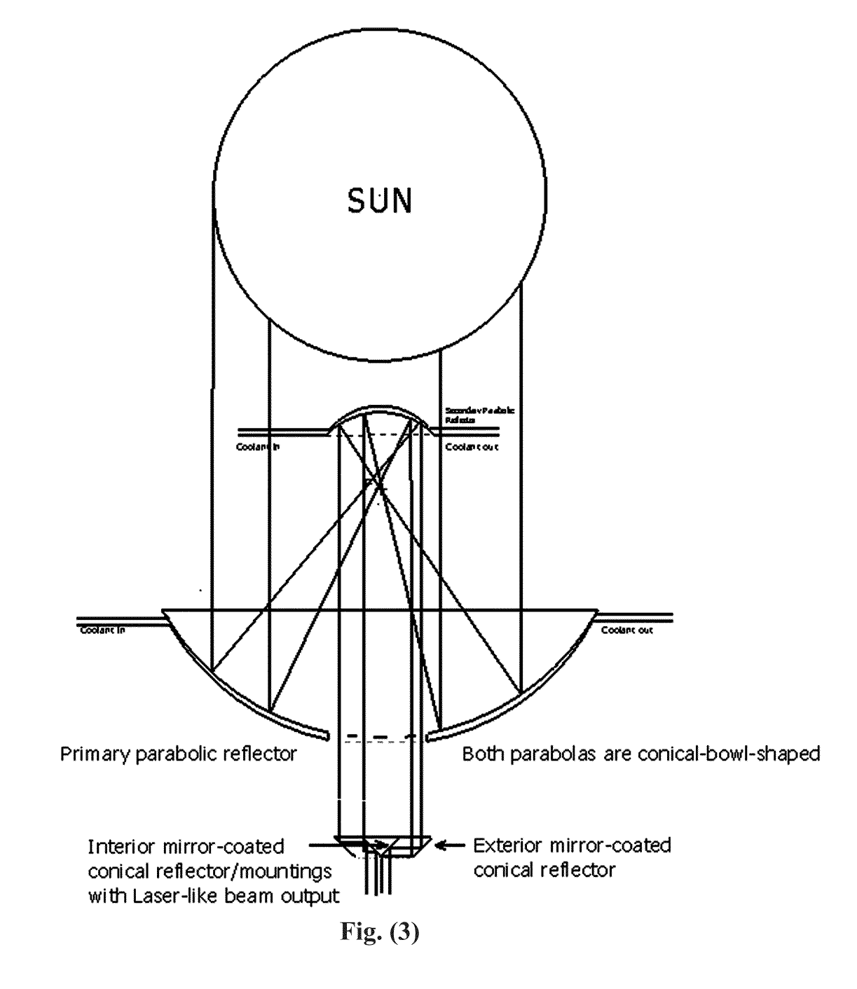

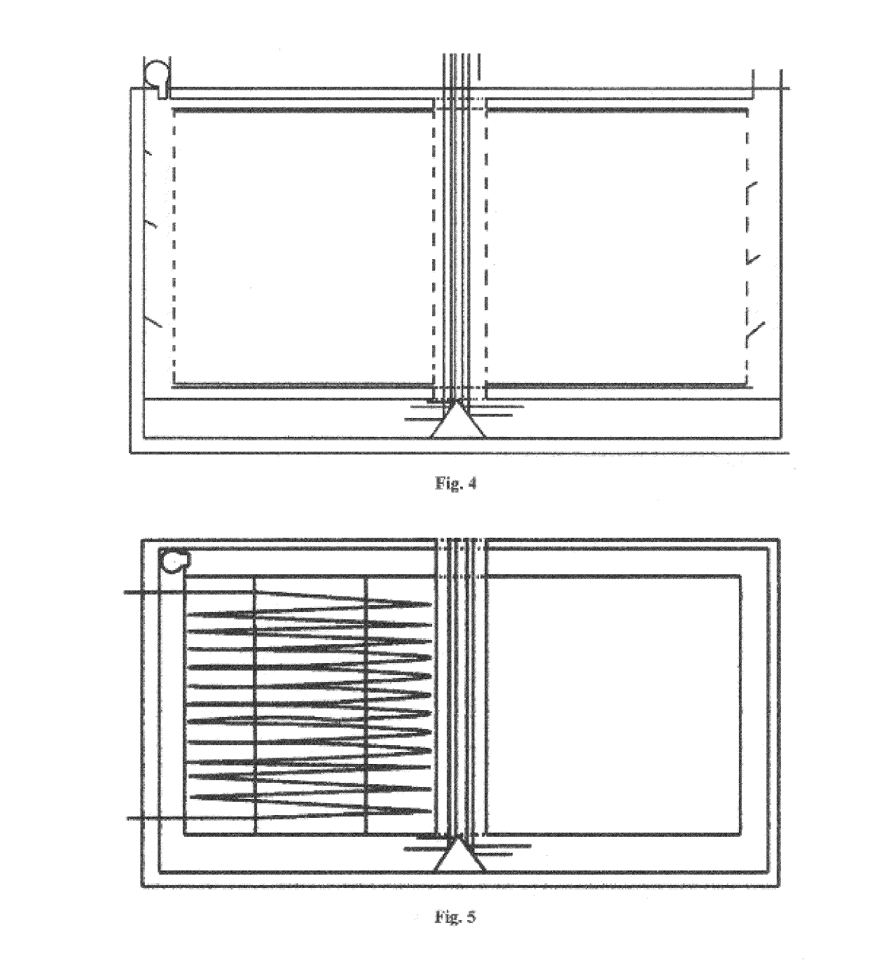

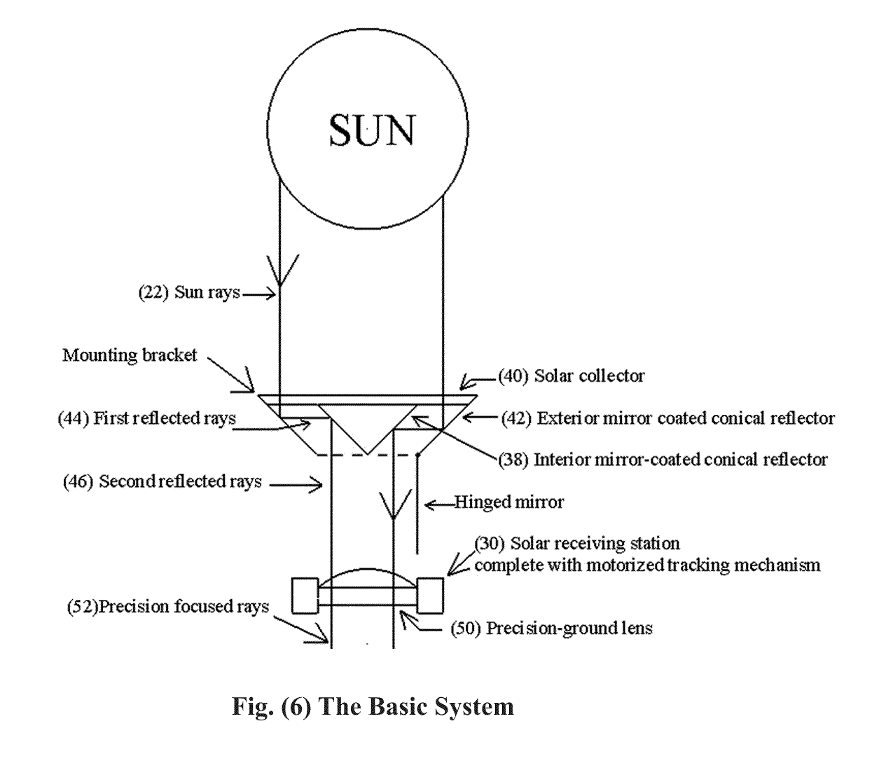

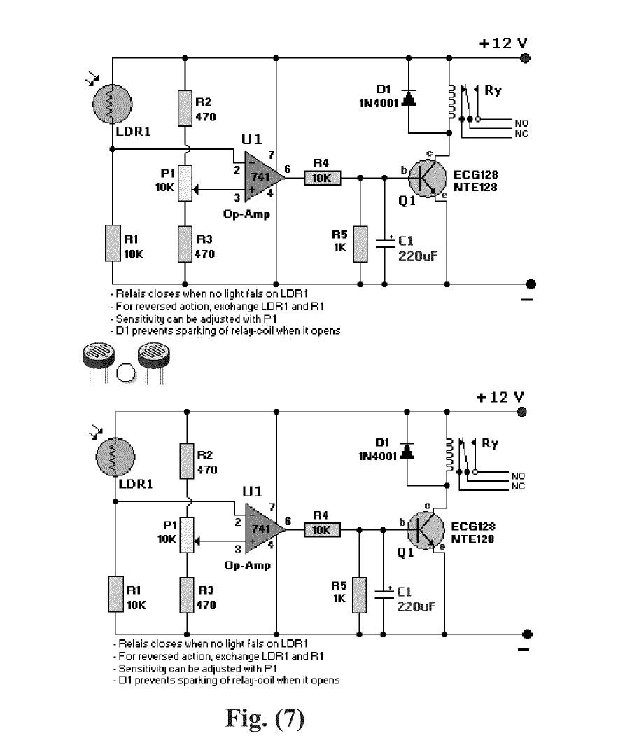

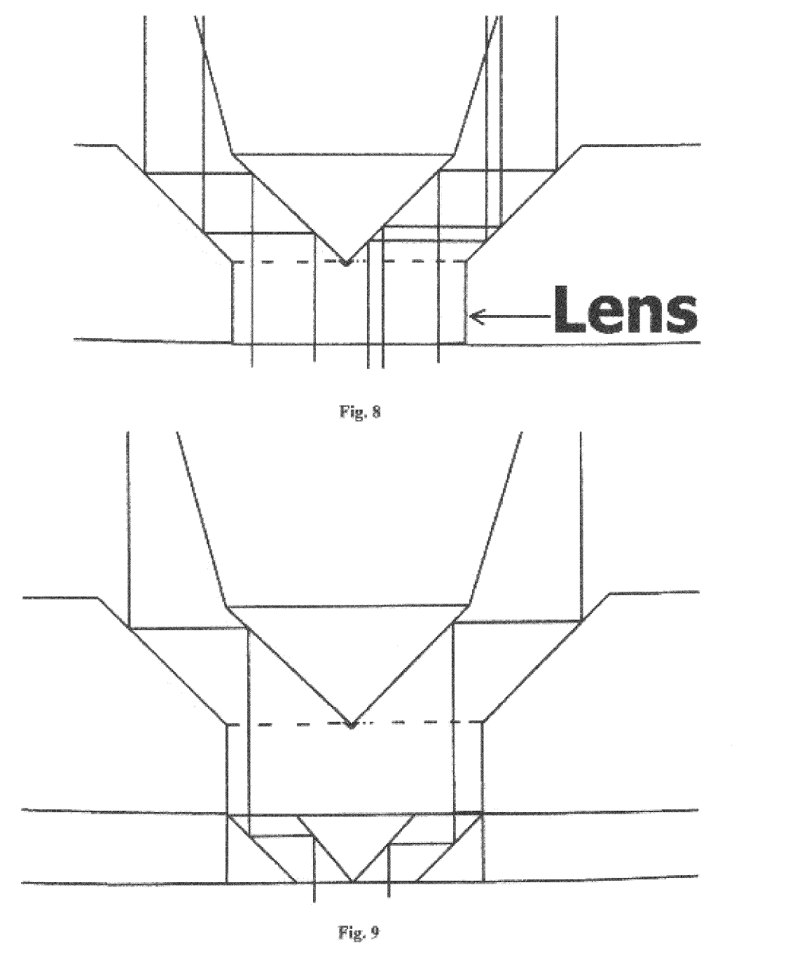

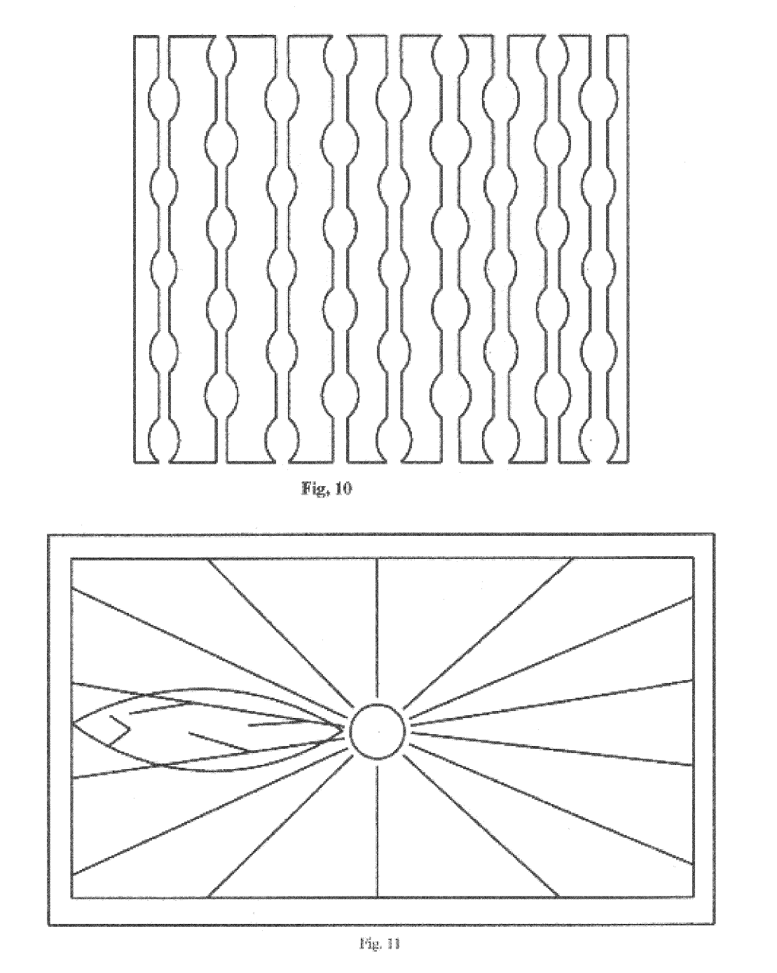

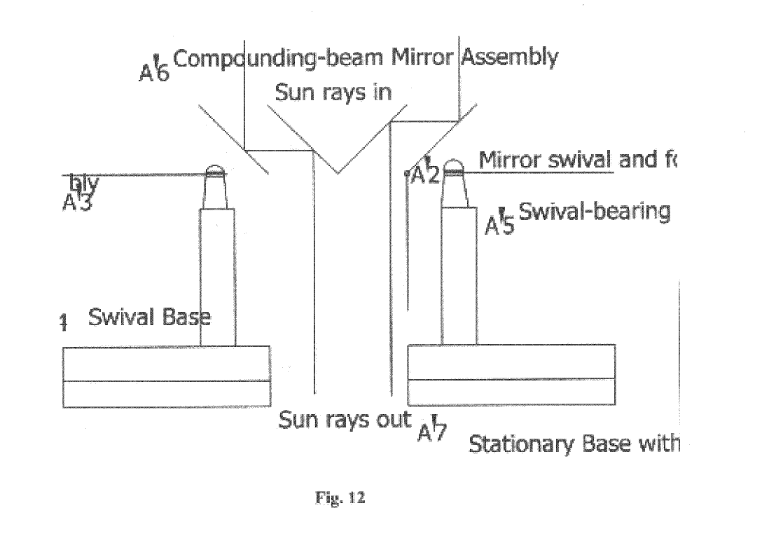

FIG. 8 and FIG. 9 also is illustrating enlarged drawing-sections of the single and double lenses assemblies that applies to this invention and, which is currently covered by U.S. Provisional Patent Application Ser. No. 61/214,463 as filed on Apr. 24, 2009; Utility Patent Application 12/563/213 date Sep. 21, 2009.

FIG. 10, illustrates a side view of one possible heat exchanger arrangement of the forced air furnace.

FIG. 11, illustrates a bottom view of one possible heat exchanger arrangement of the forced air furnace and can apply to all of the above apparatuses.

FIG. 12, is a rudimentary drawing and illustrates the alt-azimuth type mount that applies to all of the above roof mounted apparatus arrangements. One of the LDR controlled motors will position the altitude at the focal point, while the other LDR controlled motor will position the azimuth at the base of the Solar Collector Unit.

What is claimed is;

1. A solar light-energy collection and distribution system for reducing the power consumption of a plurality of loads comprising: means for tracking the Sun when it is visible;

2. A solar light-energy collection and distribution system for reducing the power consumption of a plurality of loads comprising: means for tracking the Sun when it is not visible;

3. A solar light-energy collection and distribution system for reducing the power consumption of a plurality of loads comprising: means for collecting the solar rays of the sun;

4. A solar light-energy collection and distribution system tor reducing the power consumption of a plurality of loads comprising: means for compounding the solar rays of the sun;

5. A solar light-energy collection and distribution system for reducing the power consumption of a plurality of loads comprising: means for focusing the light rays into a coherent beam for distribution;

6. A solar light-energy collection and distribution system for reducing the power consumption of a plurality of loads comprising: means for a powerful high energy solar light-ray system;

7. A solar light-energy collection and distribution system fur reducing the power consumption of a plurality of loads comprising: means for significantly increasing the output power of the light beam as desired.

8. A solar light-energy collection and distribution system for reducing the power consumption of a plurality of loads comprising: means for a powerful small-beam light-energy for traveling relatively long distances in a highly collimated form;

9. A solar light-energy collection and distribution system for reducing the power consumption of a plurality of loads comprising: means for a powerful light-energy system to limit the spread of light over a relatively long distance;

10. A solar light-energy collection and distribution system for reducing the power consumption of a plurality of loads comprising: means tor distributing the light rays to an end destination for beneficial use.

11. A solar light-energy collection and distribution system as recited in claim 1 and further includes means responsive to an undetermined condition and operative to override and/or augment said first sunlight means, whereby the coupling of backup-energy from a second source means is resumed.

12. A solar light-energy collection and distribution system as recited in claim 1 and further includes means to substitute a second source backup means for when the Sun's rays are insufficient for a particular application.
